(19) United States
(12) Patent Application Publication
(10) Pub. No.: US 2026/0255579 A1
(43) Pub. Date: Aug. 27, 2026

(54) CAPACITOR STRUCTURE AND METHOD OF FORMING THE SAME, AND SEMICONDUCTOR DEVICE INCLUDING THE CAPACITOR STRUCTURE

(71) Applicant: Samsung Electronics Co., Ltd., Suwon-si (KR)

(72) Inventors: Jungmin Park, Suwon-si (KR); Younglim Park, Suwon-si (KR); Chanhoon Park, Suwon-si (KR); Beomjong Kim, Suwon-si (KR); Hyungsuk Jung, Suwon-si (KR)

(21) Appl. No.: 19/427,765

(22) Filed: Dec. 19, 2025

(30) Foreign Application Priority Data
Feb. 24, 2025 (KR) 10-2025-0023646

(51) Int. Cl. H10B 12/00

(52) U.S. Cl. CPC H10B 12/315; H10B 12/033

(57) ABSTRACT

An example capacitor structure includes a lower electrode on a substrate, a support layer on a sidewall of a first portion of the lower electrode, a first interface pattern on a surface of the support layer and including a plurality of first patterns spaced apart from each other in a horizontal direction parallel to an upper surface of the substrate, a dielectric pattern on a sidewall of a second portion of the lower electrode, and an upper electrode on a sidewall of the dielectric pattern.

### CROSS-REFERENCE TO RELATED APPLICATION

This application claims priority under 35 U.S.C. § 119 to Korean Patent Application No. 10-2025-0023646 filed on February 24, 2025 in the Korean Intellectual Property Office, the disclosure of which is hereby incorporated by reference in its entirety.

### BACKGROUND

A capacitor structure of a DRAM device includes a capacitor having a lower electrode, a dielectric layer and an upper electrode sequentially stacked, and support layers contacting a surface of the lower electrode and being spaced apart from each other in a vertical direction and including an insulating material. A parasitic capacitance may be generated at a portion of the support layer between the upper electrode and the lower electrode. The parasitic capacitance may adversely affect the operating characteristics of the DRAM device, and thus measures to minimize it are desired.

### SUMMARY

The present disclosure relates to a capacitor structure having improved characteristics, a semiconductor device including a capacitor structure having improved characteristics, and a method of forming a capacitor structure having improved characteristics.

In some implementations, a capacitor structure may include a lower electrode on a substrate, a support layer on a sidewall of a first portion of the lower electrode, a first interface pattern on a surface of the support layer and including a plurality of first patterns spaced apart from each other in a horizontal direction parallel to an upper surface of the substrate, a dielectric pattern on a sidewall of a second portion of the lower electrode, and an upper electrode on a sidewall of the dielectric pattern.

In some implementations, a capacitor structure may include a lower electrode on a substrate, the lower electrode including a first metal, a support layer on a sidewall of a first portion of the lower electrode, a first interface pattern disposed on a surface of the support layer and protruding from the surface of the support layer in a vertical direction perpendicular to an upper surface of the substrate and including a second metal different from the first metal, a dielectric pattern on a sidewall of a second portion of the lower electrode, and an upper electrode on a sidewall of the dielectric pattern.

In some implementations, a semiconductor device may include an active pattern on a substrate, a gate structure in an upper portion of the active pattern and extending in a first direction parallel to an upper surface of the substrate, a bit line structure extending in a second direction parallel to the upper surface of the substrate and crossing the first direction and being disposed on a central portion of the active pattern, a contact plug structure on each of opposite end portions of the active pattern, and a capacitor structure on the contact plug structure. The capacitor structure may include a lower electrode on the contact plug structure, a support layer on a sidewall of a first portion of the lower electrode, a first interface pattern on a surface of the support layer and including a plurality of first patterns spaced apart from each other in a horizontal direction parallel to an upper surface of the substrate, a dielectric pattern on a sidewall of a second portion of the lower electrode, and an upper electrode on a sidewall of the dielectric pattern.

In some implementations, in a method of forming a capacitor structure, mold layers and support layers may be alternately and repeatedly stacked on a substrate in a vertical direction perpendicular to an upper surface of the substrate. A lower electrode extending through the mold layers and the support layers may be formed. The mold layers may be removed by an etching process to form a first opening exposing a portion of the support layers and a portion of the lower electrode. A first deposition process may be performed to form a first interface pattern on a surface of the portion of the support layers exposed by the first opening. The first interface pattern may include a plurality of first patterns spaced apart from each other in a horizontal direction parallel to the upper surface of the substrate.

In some implementations, in the first deposition process, a precursor may be provided onto the substrate. A reactant may be provided onto the substrate so as to be reacted with the precursor. A purge process may be performed onto the substrate.

In some implementations, the first deposition process may be a selective deposition process, and the first interface pattern may not be formed on a sidewall of the lower electrode.

In some implementations, during the first deposition process, a second interface pattern may be formed on a sidewall of the portion of the lower electrode exposed by the first opening. The second interface pattern may include a plurality of second patterns spaced apart from each other in the vertical direction.

In some implementations, a number of the first patterns of the first interface pattern per unit area may be greater than a number of the second patterns of the second interface pattern per unit area.

In some implementations, prior to performing the first deposition process, a second deposition process may be performed to form a second interface pattern on a surface of the portion of the support layers exposed by the first opening. In the first deposition process, the first interface pattern may be formed on a surface of the second interface pattern exposed by the first opening.

In some implementations, after forming the first interface pattern, a dielectric pattern and an upper electrode may be sequentially formed in the first opening. The dielectric pattern may contact the first interface pattern and the support layers.

In some implementations, the first interface pattern may include at least one of niobium, tantalum, vanadium, molybdenum, tungsten, ruthenium, titanium, zirconium, or hafnium.

The capacitor structure may include the lower electrode, the upper electrode, the dielectric pattern between the lower and upper electrodes, and the support layer on the sidewall of the dielectric pattern. The interface pattern including a leaky metal may be disposed on the surface of the support layer, and may suppress a parasitic capacitance generated between the lower electrode and the upper electrode by preventing charge accumulation on the surface of the support layer. Thus, the capacitor structure and the semiconductor device including the capacitor structure may have improved electrical characteristics.

### BRIEF DESCRIPTION OF THE DRAWINGS

FIGS. 1, 2, and 3 are cross-sectional views illustrating an example of a capacitor structure.

FIGS. 4, 5, 6, 7, 8, 9, 10, 11, and 12 are cross-sectional views illustrating an example of a method of forming a capacitor structure.

FIGS. 13, 14, 15, and 16 are cross-sectional views illustrating an example of a capacitor structure.

FIGS. 17, 18, 19, 20, and 21 are cross-sectional views illustrating an example of a method of forming a capacitor structure.

FIG. 22 is a cross-sectional view illustrating an example of a capacitor structure.

FIG. 23 is a cross-sectional view illustrating an example of a method of forming a capacitor structure.

FIG. 24 is a plan view illustrating an example of a semiconductor device, and FIG. 25 is an example cross-sectional view taken along line A-A’ of FIG. 24.

FIGS. 26, 27, 28, 29, 30, 31, 32, 33, 34, 35, 36, 37, 38, 39, 40, and 41 are plan views and cross-sectional views illustrating an example of a method of manufacturing a semiconductor device.

### DETAILED DESCRIPTION

The above and other aspects and features of a capacitor structure and a method of forming the same, and a semiconductor device and a method of manufacturing the same will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of the present disclosure.

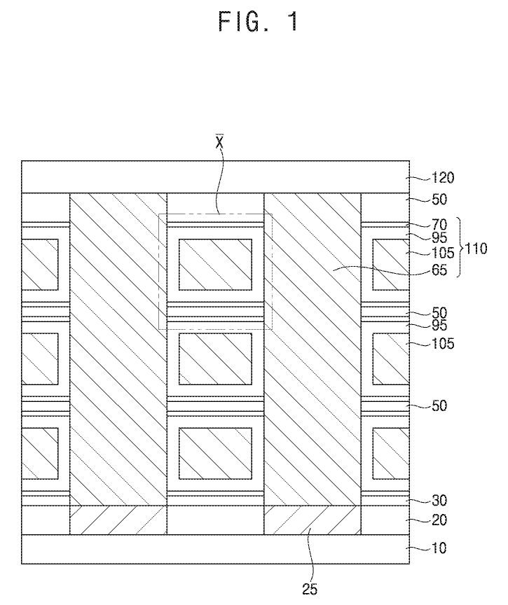

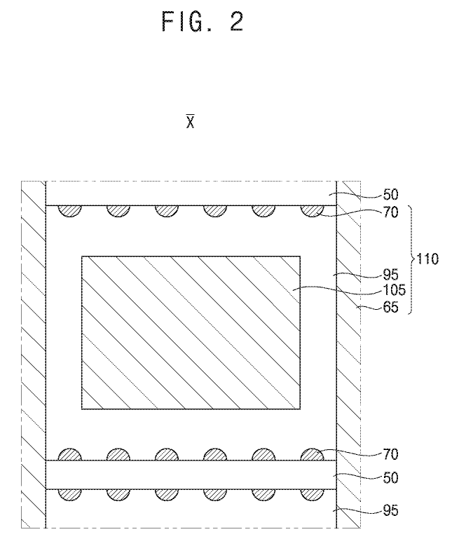

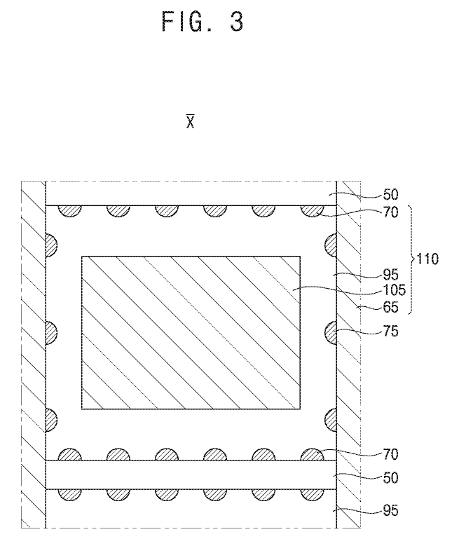

FIGS. 1, 2, and 3 are cross-sectional views illustrating an example of a capacitor structure. Each of FIGS. 2 and 3 are enlarged cross-sectional views of region X of FIG. 1.

Referring to FIGS. 1 to 3, the capacitor structure may include a capacitor 110, a support layer 50, a first etch stop layer 30 and an upper plate electrode 120 on a substrate 10, and the capacitor 110 may include a lower electrode 65, a first interface pattern 70, a dielectric pattern 95 and an upper electrode 105.

An insulating interlayer 20 may be disposed on the substrate 10, and a first conductive pattern 25 contacting the lower electrode 65 may be disposed in the insulating interlayer 20.

The substrate 10 may include a semiconductor material, e.g., silicon, germanium, silicon-germanium, etc., or a III-V group compound semiconductor, e.g., GaP, GaAs, GaSb, etc. In some implementations, the substrate 10 may be a silicon-on-insulator (SOI) substrate or a germanium-on-insulator (GOI) substrate.

The first conductive pattern 25 may include, e.g., a contact plug, a landing pad, etc., and a plurality of first conductive patterns 25 may be spaced apart from each other in a horizontal direction parallel to an upper surface of the substrate 10. The first conductive pattern 25 may include, e.g., a metal, a metal nitride, a metal silicide, doped polysilicon, etc. The insulating interlayer 20 may include, e.g., an oxide such as silicon oxide or a low-k dielectric material.

The first etch stop layer 30 may be disposed on the insulating interlayer 20. The first etch stop layer 30 may include an insulating nitride, e.g., silicon nitride, silicon boron nitride, silicon carbonitride, etc.

The lower electrode 65 may extend through the first etch stop layer 30, and contact an upper surface of the first conductive pattern 25. The lower electrode 65 may have a shape of a pillar extending in a vertical direction perpendicular to the upper surface of the substrate 10. However, the present disclosure is not limited thereto, and the lower electrode 65 may have a shape of a cup or a hollow cylinder. If the lower electrode 65 has the cup shape, a filling pattern including a semiconductor material, e.g., amorphous silicon or an insulating material may be disposed in an inner space defined by the lower electrode 65.

In some implementations, the lower electrode 65 may include a conductive material, e.g., a metal, a metal nitride such as titanium nitride, molybdenum nitride, vanadium nitride, chromium nitride, hafnium nitride, zirconium nitride, tungsten nitride, etc., or a metal silicon nitride such as titanium silicon nitride. FIG. 1 shows that the lower electrode 65 has a single-layered structure, however, the present disclosure is not limited thereto, and the lower electrode 65 may have a multi-layered structure including different conductive materials.

The support layer 50 may be disposed on a sidewall of the lower electrode 65, and may have a shape of a flat plate including upper and lower surfaces extending in a horizontal direction parallel to the upper surface of the substrate 10. In some implementations, a plurality of support layers 50 may be spaced apart from each other in a vertical direction perpendicular to the upper surface of the substrate 10 on the first etch stop layer 30.

The support layer 50 may include an insulating nitride, e.g., silicon nitride, silicon boron nitride, silicon carbonitride, etc.

The first interface pattern 70 may be disposed on and partially cover a lower surface of an uppermost one of the support layers 50, upper and lower surfaces of other ones of the support layers 50, and an upper surface of the first etch stop layer 30.

The first interface pattern 70 may include first patterns spaced apart from each other in the horizontal direction. Thus, an empty space may exist between neighboring ones of the first patterns in the horizontal direction, and thus neighboring ones of the lower electrodes 65 in the horizontal direction may not be electrically connected to each other due to the first interface pattern 70.

In some implementations, as shown in FIG. 2, the first interface pattern 70 may be disposed on the upper and lower surfaces of each of the support layers 50 and the upper surface of the first etch stop layer 30, and may not be disposed on a sidewall of the lower electrode 65.

Alternatively, as shown in FIG. 3, a second interface pattern 75 may be disposed on the sidewall of the lower electrode 65. Like the first interface pattern 70, the second interface pattern 75 may include a plurality of second patterns spaced apart from each other in the vertical direction. In some implementations, a distance between the second patterns may be greater than a distance between the first patterns. Thus, the number of the first patterns of the first interface pattern 70 per unit area may be greater than the number of the second patterns of the second interface pattern 75 per unit area.

In some implementations, a proportion occupied by each of the first and second interface patterns 70 and 75 on surfaces of the support layer 50 and the lower electrode 65 may be equal to or less than about 5%.

Each of the first patterns of the first interface pattern 70 may protrude from the lower surface of the uppermost one of the support layers 50, the upper and lower surfaces of the other ones of the support layers 50, and the upper surface of the first etch stop layer 30, and a cross-section in the vertical direction of each of the first patterns may have a shape of, e.g., a circle, an ellipse, a rectangle, etc. Additionally, each of the second patterns of the second interface pattern 75 may protrude from the sidewall of the lower electrode 65, and a cross-section in the vertical direction of each of the second patterns may have a shape of, e.g., a circle, an ellipse, a rectangle, etc. FIGS. 2 and 3 show that the first patterns are spaced apart from each other in the horizontal direction by a constant distance and the second patterns are spaced apart from each other in the vertical direction by a constant distance, however, the present disclosure is not limited thereto. Thus, in some implementations, the first patterns are spaced apart from each other in the horizontal direction by different distances from each other, and the second patterns are spaced apart from each other in the vertical direction by different distances.

Each of the first and second interface patterns 70 and 75 may include a leaky metal, e.g., a transition metal. Particularly, the first interface pattern 70 may include at least one of niobium, tantalum, vanadium, molybdenum, titanium, chromium, manganese, iron, cobalt, copper, zinc, zirconium, ruthenium, rhodium, palladium, hafnium, iridium, platinum, or tungsten, or an oxide, a carbide, or a nitride of the above metals.

The dielectric pattern 95 may be disposed between the first etch stop layer 30 and a lowermost one of the support layers 50 and between the support layers 50, and may contact a sidewall of the lower electrode 65. Additionally, the dielectric pattern 95 may also contact an upper surface of the first etch stop layer 30, a lower surface of an uppermost one of the support layers 50, and lower and upper surfaces of other ones of the support layers 50. In some implementations, the dielectric pattern 95 may contact the second interface pattern 75 on the sidewall of the lower electrode 65.

The dielectric pattern 95 may include a metal oxide. In some implementations, the dielectric pattern 95 may include a high-k dielectric material, e.g., hafnium oxide, zirconium oxide, titanium oxide, tantalum oxide, strontium titanium oxide, barium titanium oxide, etc.

A surface of the upper electrode 105 may be covered by the dielectric pattern 95, and the upper electrode 105 may be disposed between the first etch stop layer 30 and the lowermost one of the support layers 50 and between the support layers 50.

The upper electrode 105 may include substantially the same material as the lower electrode 65, or a different material from the lower electrode 65.

The upper plate electrode 120 may be disposed on the lower electrode 65 and the uppermost one of the support layers 50, and may include, e.g., doped silicon-germanium.

As illustrated above, the capacitor structure may include the capacitor 110 having the lower electrode 65, the dielectric pattern 95 and the upper electrode 105, and the support layers 50 spaced apart from each other in the vertical direction on the sidewall of the lower electrode 65. A parasitic capacitance may be generated at a portion of the support layer 50 between the lower electrode 65 and the upper electrode 105.

However, in some implementations, the first interface pattern 70 including a leaky metal may be disposed on the surface of each of the support layers 50, and may suppress the parasitic capacitance generated between the lower electrode 65 and the upper electrode 105 by preventing charge accumulation on the surface of each of the support layers 50.

The first interface pattern 70 may not be disposed continuously between the lower electrodes 65, but may include a plurality of first patterns spaced apart from each other in the horizontal direction, and thus, even though the first interface pattern 70 exists, an electrical short between neighboring ones of the lower electrodes 65 in the horizontal direction or leakage current therefrom may be prevented.

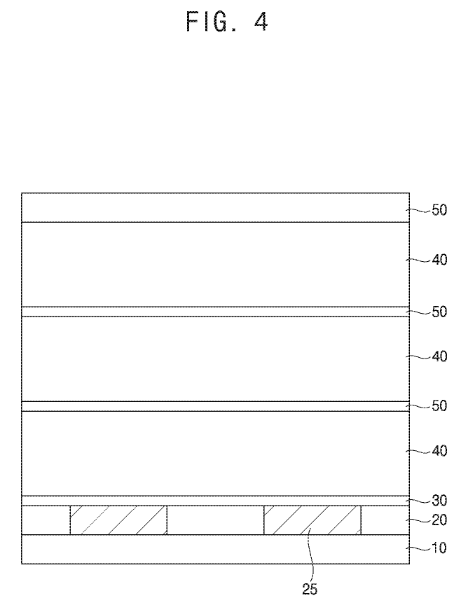

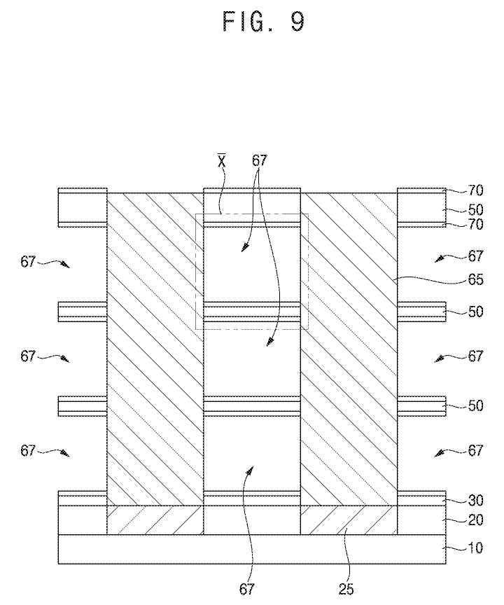

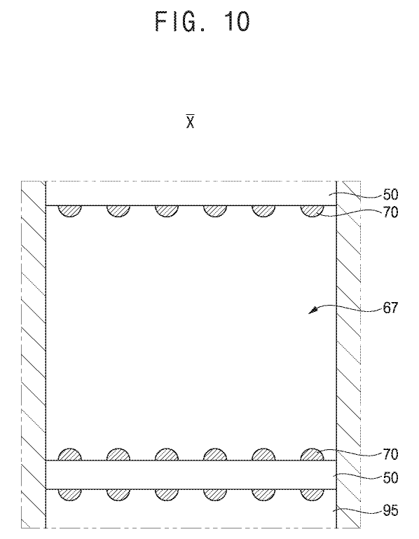

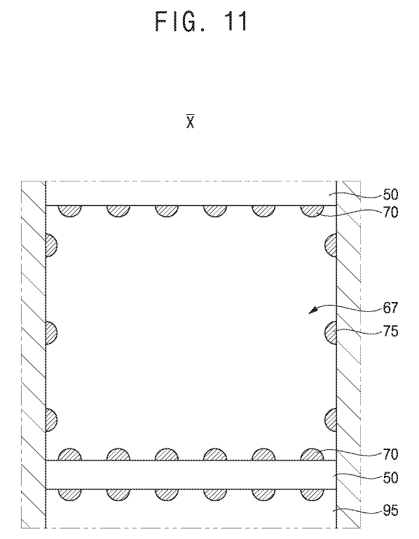

FIGS. 4, 5, 6, 7, 8, 9, 10, 11, and 12 are cross-sectional views illustrating an example of a method of forming a capacitor structure. FIGS. 10 and 11 are enlarged cross-sectional views of region X of FIG. 9.

Referring to FIG. 4, an insulating interlayer 20 may be formed on a substrate 10, a first conductive pattern 25 may be formed through the insulating interlayer 20, a first etch stop layer 30 may be formed on the insulating interlayer 20 and the first conductive pattern 25, and a mold layer 40 and a support layer 50 may be alternately and repeatedly stacked on the first etch stop layer 30.

In some implementations, a plurality of first conductive patterns 25 may be formed to be spaced apart from each other in a horizontal direction parallel to an upper surface of the substrate 10.

The mold layer 40 may include an oxide, e.g., silicon oxide or a low-k dielectric material.

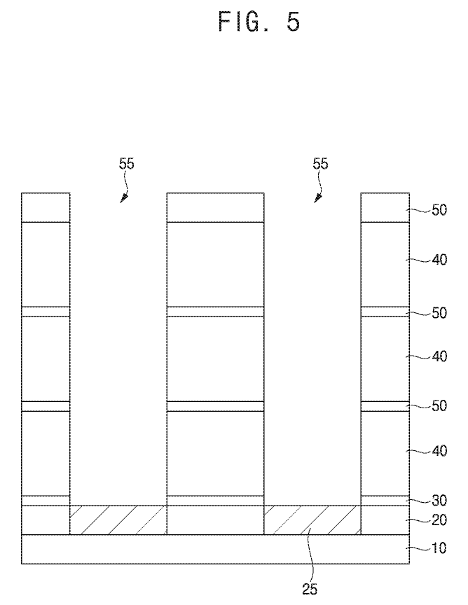

Referring to FIG. 5, a first opening 55 may be formed through the support layer 50, the mold layer 40 and the first etch stop layer 30 to expose an upper surface of each of the first conductive patterns 25.

In some implementations, the first opening 55 may be formed by forming an etching mask on an uppermost one of the support layers 50 and performing a dry etching process using the etching mask.

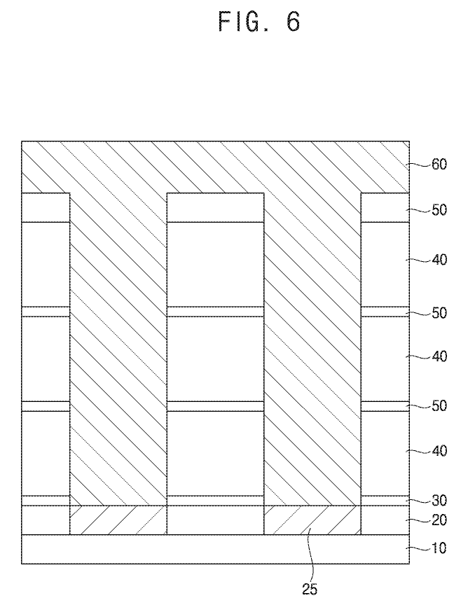

Referring to FIG. 6, a lower electrode layer 60 may be formed on the upper surface of the first conductive pattern 25 exposed by the first opening 55 and an upper surface of the uppermost one of the support layers 50 to fill the first opening 55.

In some implementations, the lower electrode layer 60 may include, e.g., a metal or a metal nitride.

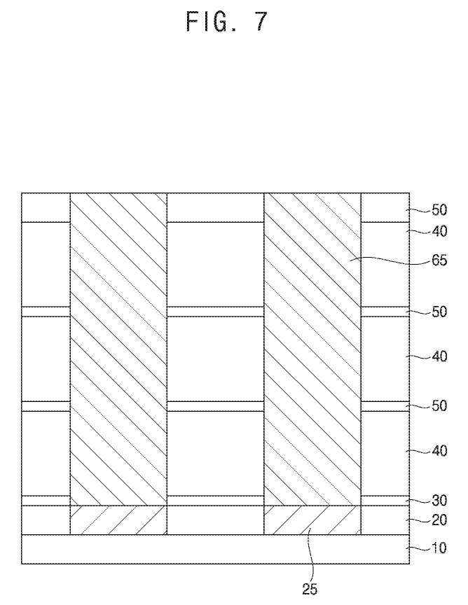

Referring to FIG. 7, a planarization process may be performed on the lower electrode layer 60 until the upper surface of the uppermost one of the support layers 50 is exposed to form a lower electrode 65.

The planarization process may include a chemical mechanical polishing (CMP) process and/or an etch back process.

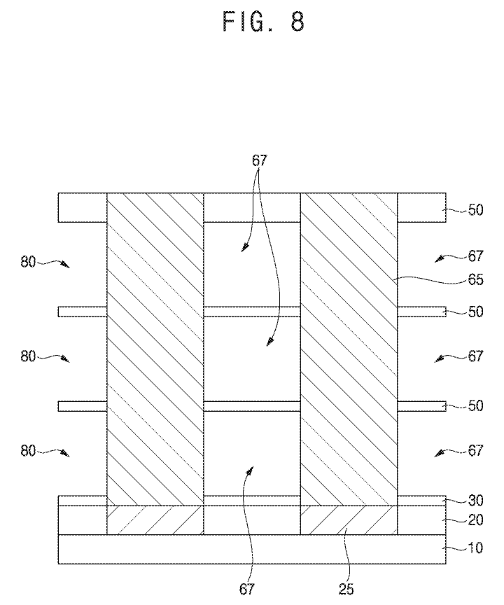

Referring to FIG. 8, the support layer 50 and the mold layer 40 may be partially removed by, e.g., a wet etching process to form a second opening exposing an upper surface of the first etch stop layer 30, and the mold layer 40 may be removed through the second opening.

In some implementations, the mold layer 40 may be removed by a wet etching process, and a third opening 67 may be formed to expose a sidewall of the lower electrode 65. However, the support layers 50 may remain on the sidewall of the lower electrode 65.

By the third opening 67, the upper surface of the first etch stop layer 30 and a surface of each of the support layers 50 may also be exposed.

Referring to FIGS. 9 to 11, a first interface pattern 70 may be formed on the surface of each of the support layers 50 and the upper surface of the first etch stop layer 30 exposed by the third opening 67.

The first interface pattern 70 may be formed by a deposition process, e.g., an atomic layer deposition (ALD) process. When the ALD process is performed, by adjusting a supply time of a precursor and a reactant, the first interface pattern 70, which may be formed by a chemical reaction between the precursor and the reactant, may be formed discontinuously rather than continuously on the surfaces of the support layers and the upper surface of the first etch stop layer 30. Thus, the first interface pattern 70 may be formed to include a plurality of first patterns spaced apart from each other in the horizontal direction on the surfaces of the support layers and the upper surface of the first etch stop layer 30. After providing the precursor and the reactant onto the substrate 10, a purge process may be further performed.

In some implementations, as shown in FIG. 10, the first interface pattern 70 may be selectively formed on the surfaces of the support layers 50 including an insulating material and the upper surface of the first etch stop layer 30 including an insulating material. Alternatively, as shown in FIG. 11, a second interface pattern 75 may be further formed on the sidewall of the lower electrode 65 including a conductive material.

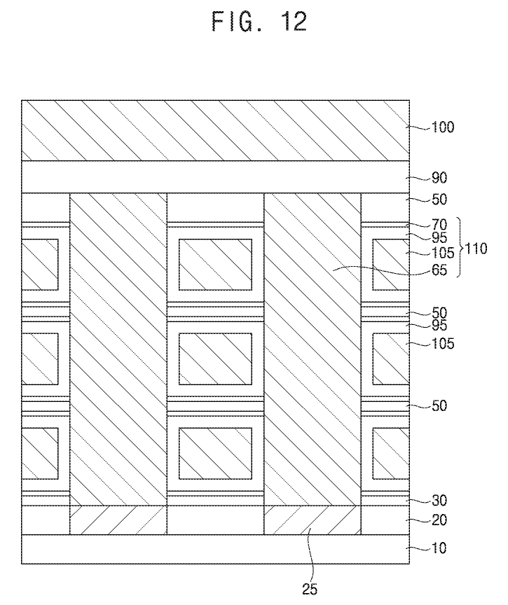

Referring to FIG. 12, a dielectric layer 90 may be formed on the sidewall of the lower electrode 65, the upper surface of the first etch stop layer 30, the surface of each of the support layers 50 and a surface of the first interface pattern 70 exposed by the third opening 67, and an upper electrode layer 100 may be formed on the dielectric layer 90 to fill the third opening 67.

The dielectric layer 90 may include, e.g., hafnium oxide, zirconium oxide, or a compound thereof.

The dielectric layer 90 and the upper electrode layer 100 may also be formed on an upper surface of the lower electrode 65 and the upper surface of the uppermost one of the support layers 50.

Referring to FIGS. 1 to 3 again, portions of the dielectric layer 90, the upper electrode layer 100 and the first interface pattern 70 on the upper surface of the lower electrode 65 and the uppermost one of the support layers 50 may be removed.

Thus, the dielectric layer 90 and the upper electrode layer 100 may remain as a dielectric pattern 95 and an upper electrode 105, respectively, in the third opening 67.

The lower electrode 65, the dielectric pattern 95 and the upper electrode 105 may collectively form a capacitor 110.

An upper plate electrode 120 may be further formed on the capacitor 110 to complete the formation of the capacitor structure.

As illustrated above, the first interface pattern 70 may be formed on the surface of each of the support layers 50 and the upper surface of the first etch stop layer 30 by a deposition process such as an ALD process, and as the first interface pattern 70 is formed, the parasitic capacitance generated due to the support layer 50 and the first etch stop layer 30 between the lower electrode 65 and the upper electrode 105 may be reduced.

By adjusting a duration time of the ALD process, the first interface pattern 70 may be formed to include a plurality of first patterns spaced apart from each other in the horizontal direction. Thus, the first interface pattern 70 may not be continuously formed on the surface of each of the support layers 50 and the upper surface of the first etch stop layer 30 but may be discontinuously formed, and the electrical short between neighboring ones of the lower electrodes 65 in the horizontal direction or the leakage current from the lower electrodes 65 may be prevented.

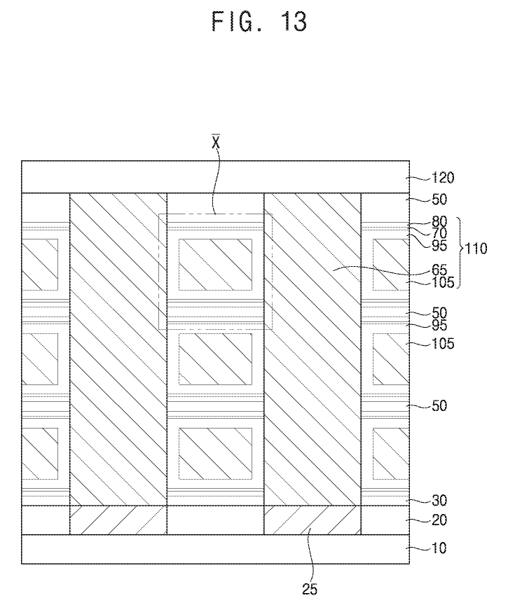

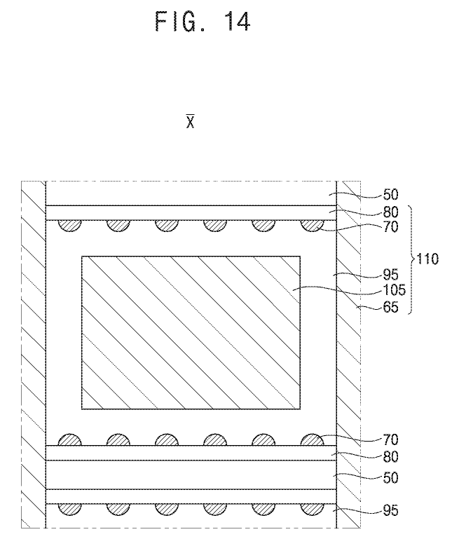

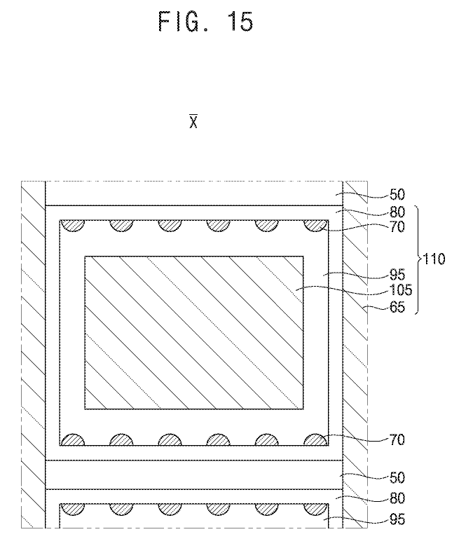

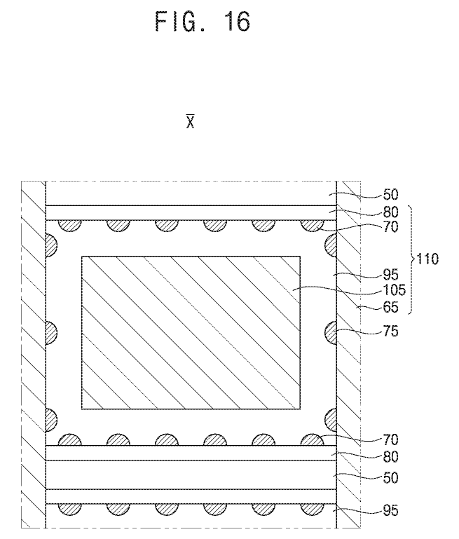

FIGS. 13, 14, 15, and 16 are cross-sectional views illustrating an example of a capacitor structure. FIG. 13 may correspond to FIG. 1, FIGS. 14 and 15 may correspond to FIG. 2, and FIG. 16 may correspond to FIG. 3. Each of FIGS. 14 to 16 are enlarged cross-sectional views of region X of FIG. 13.

The capacitor structure may be substantially the same as or similar to that of FIGS. 1 to 3, except for further including a third interface pattern, and thus repeated explanations are omitted herein.

Referring to FIGS. 13 to 16, the capacitor 110 may further include a third interface pattern 80 between each of the support layers 50 and the first interface pattern 70 and between the first etch stop layer 30 and the first interface pattern 70.

In some implementations, as shown in FIG. 14, the third interface pattern 80 may contact the lower surface of the uppermost one of the support layers 50, the lower and upper surfaces of other ones of the support layers 50, and the upper surface of the first etch stop layer 30, and each of the first patterns of the first interface pattern 70 may protrude from the third interface pattern 80 in the vertical direction. Alternatively, as shown in FIG. 15, the third interface pattern 80 may also contact the sidewall of the lower electrode 65.

In some implementations, as shown in FIG. 14, the first interface pattern 70 may be disposed on a surface of the third interface pattern 80, and may not be disposed on the sidewall of the lower electrode 65.

Alternatively, as shown in FIG. 16, the second interface pattern 75 may be disposed on the sidewall of the lower electrode 65. Like the first interface pattern 70, the second interface pattern 75 may include a plurality of second patterns spaced apart from each other in the vertical direction. In some implementations, a distance between the second patterns may be greater than a distance between the first patterns. Thus, the number of the first patterns of the first interface pattern 70 per unit area may be greater than the number of the second patterns of the second interface pattern 75 per unit area.

In some implementations, the third interface pattern 80 may include an oxide, e.g., silicon oxide.

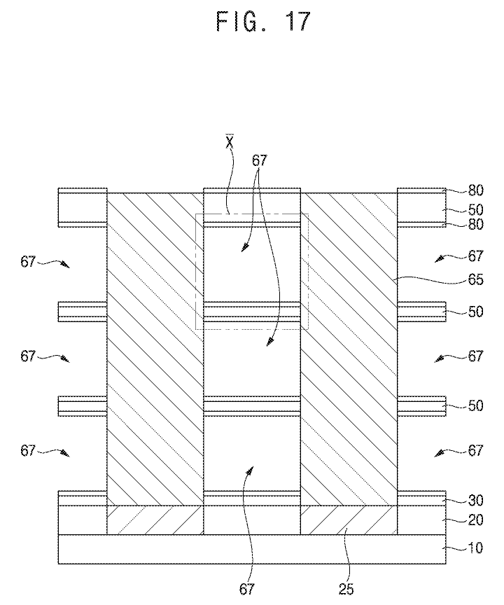

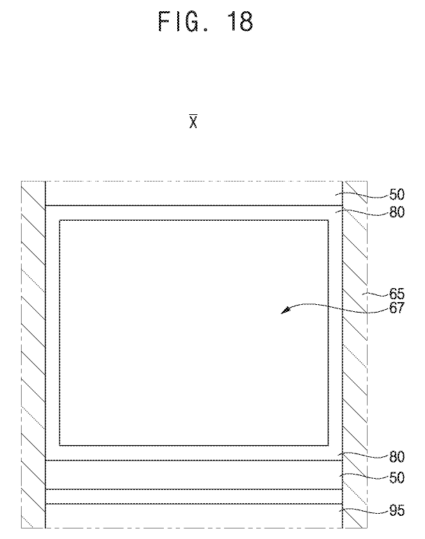

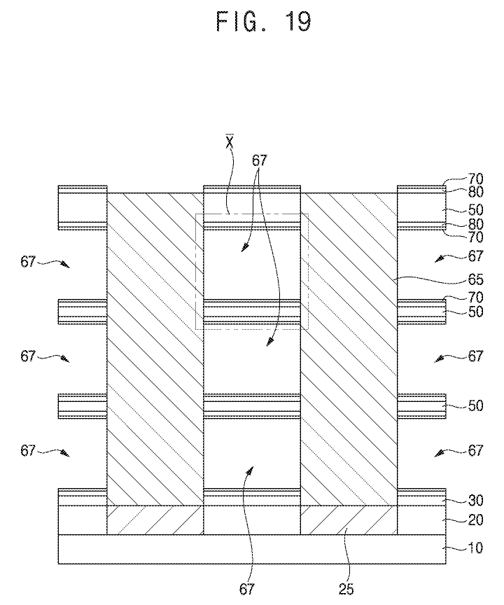

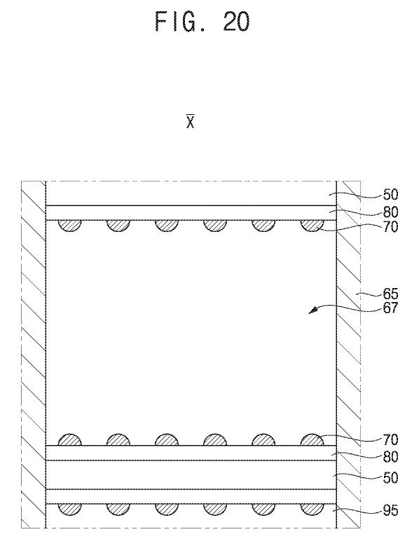

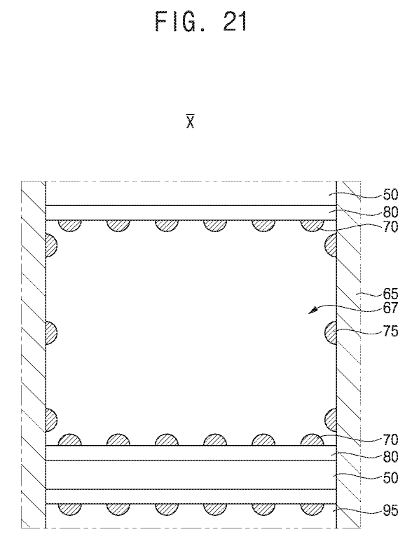

FIGS. 17, 18, 19, 20, and 21, are cross-sectional views illustrating an example of a method of forming a capacitor structure. FIG. 18 is an enlarged cross-sectional view of region X of FIG. 17, and each of FIGS. 20 and 21 are enlarged cross-sectional views of region X of FIG. 19.

This method may include processes substantially the same as or similar to those illustrated with respect to FIGS. 4 to 12 and FIGS. 1 to 3, and thus repeated explanations are omitted herein.

Referring to FIG. 17, processes substantially the same as or similar to those illustrated with respect to FIGS. 4 to 8 may be performed, and a third interface pattern 80 may be formed on the support layers 50 and the first etch stop layer 30 exposed by the third opening 67.

In some implementations, the third interface pattern 80 may be formed by a deposition process, e.g., an ALD process. In some implementations, the third interface pattern 80 may be selectively formed on a surface of a structure including an insulating material. Thus, as shown in FIG. 17, the third interface pattern 80 may be formed on the lower surface of the uppermost one of the support layers 50, the lower and upper surfaces of other ones of the support layers 50 and the upper surface of the first etch stop layer 30 exposed by the third opening 67. Alternatively, as shown in FIG. 18, the third interface pattern 80 may be formed on the sidewall of the lower electrode 65 exposed by the third opening 67.

Referring to FIGS. 19 to 21, processes substantially the same as or similar to those illustrated with respect to FIGS. 9 to 11 may be performed to form the first interface pattern 70 on a surface of the third interface pattern 80.

In some implementations, as shown in FIG. 20, the first interface pattern 70 may be formed on the surface of the third interface pattern 80. Alternatively, as shown in FIG. 21, the second interface pattern 75 may also be formed on the sidewall of the lower electrode 65 exposed by the third opening 67. Alternatively, the third interface pattern 80 may also be formed on the sidewall of the lower electrode 65, and the second interface pattern 70 may be formed on a sidewall of a portion of the third interface pattern 80 on the sidewall of the lower electrode 65.

Processes substantially the same as or similar to those illustrated with respect to FIG. 12 and FIGS. 1 to 3 may be performed to complete the formation of the capacitor structure.

FIG. 22 is a cross-sectional view illustrating an example of a capacitor structure, which may correspond to FIG. 1. The capacitor structure may be substantially the same as or similar to that of FIGS. 1 to 3, except for further including first and second doping regions, and thus repeated explanations are omitted herein.

Referring to FIG. 22, a first doping region 30d may be formed at an upper portion of the first etch stop layer 30, and a second doping region 50d may be formed at a lower portion of the uppermost one of the support layers 50, and lower and upper portions of other ones of the support layers 50.

Each of the first and second doping regions 30d and 50d may be doped with, e.g., carbon, and thus may include, e.g., silicon nitride or silicon boron nitride doped with carbon.

In the capacitor structure, the first and second doping regions 30d and 50d included in the support layer 50 and the first etch stop layer 30 may have leakage characteristic, and may suppress the parasitic capacitance of the portion of the support layer 50 between the lower electrode 65 and the upper electrode 105.

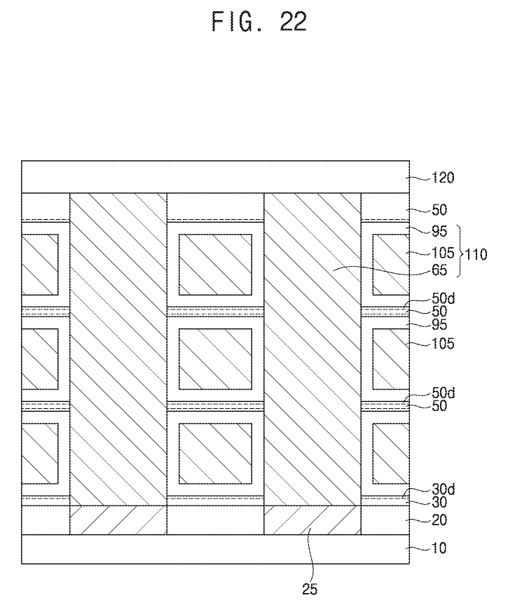

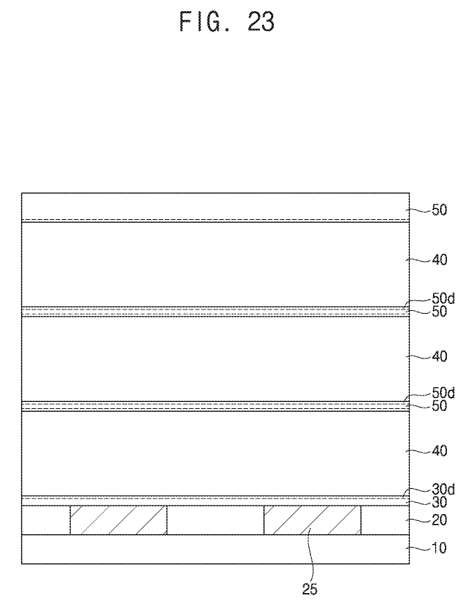

FIG. 23 is a cross-sectional view illustrating an example of a method of forming a capacitor structure. This method may include processes substantially the same as or similar to those illustrated with respect to FIGS. 4 to 12 and FIGS. 1 to 3, and thus repeated explanations are omitted herein.

Referring to FIG. 23, the insulating interlayer 20 may be formed on the substrate 10, the first conductive pattern 25 may be formed through the insulating interlayer 20, the first etch stop layer 30 may be formed on the insulating interlayer 20 and the first conductive pattern 25 by a first deposition process. A first doping region 30d may be formed in an upper portion of the first etch stop layer 30.

In some implementations, the first doping region 30d may be formed by further providing a carbon source gas in the first deposition process. Alternatively, the first doping region 30d may be formed by performing an ion implantation process in which carbon is implanted after performing the first deposition process.

A mold layer 40 and a support layer 50 may be alternately and repeatedly stacked on the first etch stop layer 30 by a second deposition process. A second doping region 50d may be formed in a lower portion of the uppermost one of the support layers 50 and lower and upper portions of other ones of the support layers 50.

In some implementations, the second doping region 50d may be formed by further providing a carbon source gas in the second deposition process.

Processes substantially the same as or similar to those illustrated with respect to FIGS. 5 to 12 and FIGS. 1 to 3 may be performed to complete the formation of the capacitor structure.

FIG. 24 is a plan view illustrating an example of a semiconductor device, and FIG. 25 is an example cross-sectional view taken along line A-A’ of FIG. 24.

This semiconductor device may be a DRAM device to which the capacitor structure of FIGS. 1 to 3 is applied, and thus repeated explanations on the capacitor structure are omitted herein.

Hereinafter, two directions substantially perpendicular to each other among horizontal directions that are substantially parallel to an upper surface of a substrate 300 may be referred to as first and second directions D1 and D2, and a direction among the horizontal direction, which may have an acute angle with respect to the first and second directions D1 and D2, may be referred to as a third direction D3. A direction substantially perpendicular to the upper surface of the substrate 300 may be referred to as a vertical direction.

The semiconductor device may include an active pattern 305, a gate structure 360, a bit line structure 595, a contact plug structure and the capacitor structure on a substrate 300.

Additionally, the semiconductor device may further include an isolation pattern 310, a spacer structure 665, a fourth spacer 690, a second capping pattern 685, first and second insulation pattern structures 435 and 790, and fourth and fifth insulation patterns 610 and 620.

The substrate 300 may include a semiconductor material, e.g., silicon, germanium, silicon-germanium, etc., or a III-V group compound semiconductor, e.g., GaP, GaAs, GaSb, etc.

The active pattern 305 may extend in the third direction D3, and a plurality of active patterns 305 may be spaced apart from each other in the first and second directions D1 and D2. The isolation pattern 310 may cover a sidewall of the active pattern 305. The active pattern 305 may include a material substantially the same as the substrate 300, and the isolation pattern 310 may include an oxide, e.g., silicon oxide.

Referring to FIGS. 12 and 13 together with FIG. 27, the gate structure 360 may be disposed in a second recess extending through upper portions of the active pattern 305 and the isolation pattern 310 in the first direction D1. The gate structure 360 may include a gate insulation pattern 330 on a bottom and a sidewall of the second recess, a gate electrode 340 on a portion of the gate insulation pattern 330 on the bottom and a lower sidewall of the second recess, and a gate mask 350 on the gate electrode 340 in an upper portion of the second recess.

The gate insulation pattern 330 may include an oxide, e.g., silicon oxide, the gate electrode 340 may include a conductive material, e.g., a metal, a metal nitride, a metal silicide, etc., and the gate mask 350 may include an insulating nitride, e.g., silicon nitride.

In some implementations, the gate structure 360 may extend in the first direction D1, and a plurality of gate structures 360 may be spaced apart from each other in the second direction D2.

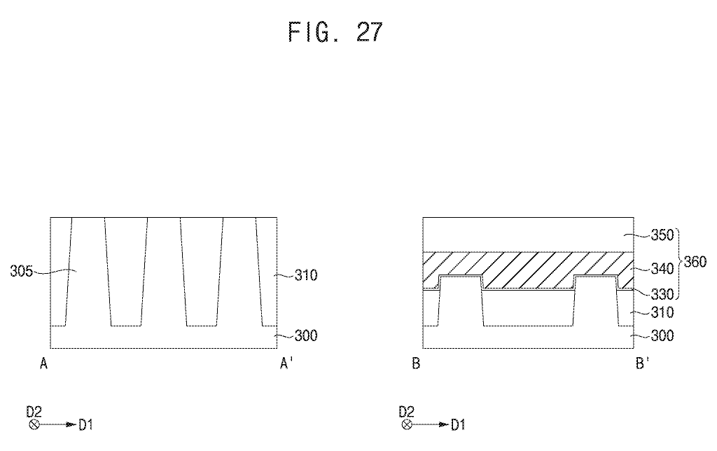

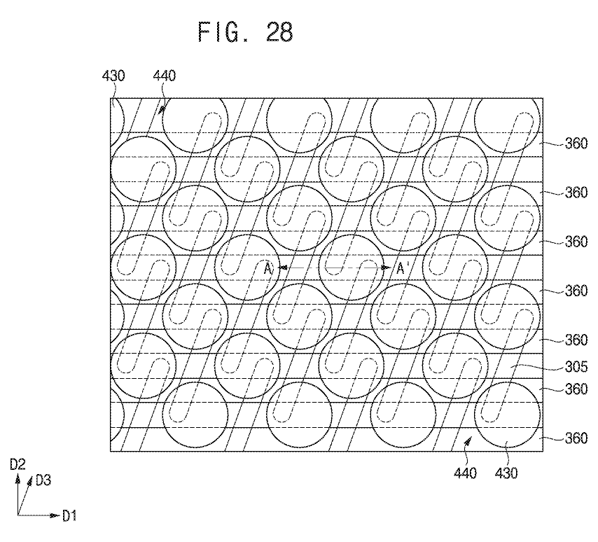

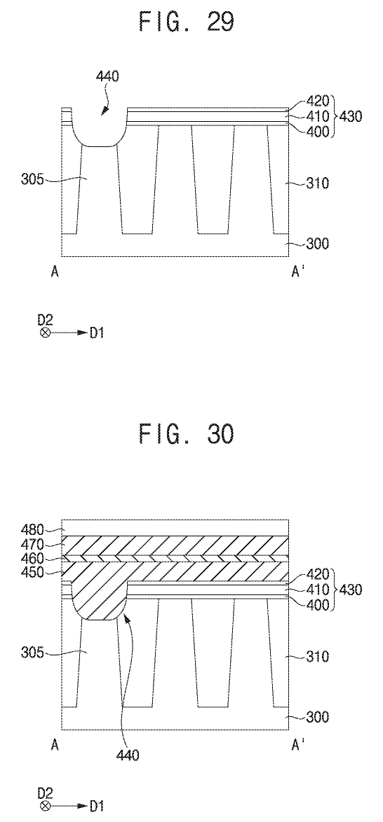

Referring to FIGS. 12 and 13 together with FIGS. 28 and 29, a fourth opening 440 may be formed through an insulation layer structure 430 and expose upper surfaces of the active pattern 305, the isolation pattern 310 and the gate mask 350 of the gate structure 360, and an upper surface of a central portion in the third direction D3 of the active pattern 305 may be exposed by the fourth opening 440.

In some implementations, a bottom of the fourth opening 440 may be wider than the upper surface of the active pattern 305 exposed by the fourth opening 440. Thus, the fourth opening 440 may also expose an upper surface of a portion of the isolation pattern 310 adjacent to the active pattern 305. The fourth opening 440 may also extend through upper portions of the active pattern 305 and the isolation pattern 310, and thus the bottom of the fourth opening 440 may be lower than an upper surface of a portion of the active pattern 305 in which the fourth opening 440 is not formed, e.g., each of opposite end portions in the third direction D3 of the active pattern 305.

The bit line structure 595 may include a first conductive pattern 455, a first barrier pattern 465, a second conductive pattern 475, a first mask 485, a second etch stop pattern 565 and a first capping pattern 585 sequentially stacked in the vertical direction on the first opening 440 or on the first insulation pattern structure 435. The first conductive pattern 455, the first barrier pattern 465 and the second conductive pattern 475 may collectively form a conductive structure, and the first mask 485, the second etch stop pattern 565 and the first capping pattern 585 may collectively form an insulation structure.

The first conductive pattern 455 may include, e.g., doped polysilicon, the first barrier pattern 465 may include a metal nitride, e.g., titanium nitride, or a metal silicon nitride, e.g., titanium silicon nitride, the second conductive pattern 475 may include a metal, e.g., tungsten, and each of the first mask 485, the second etch stop pattern 565 and the first capping pattern 585 may include an insulating nitride, e.g., silicon nitride.

In some implementations, the bit line structure 595 may extend in the second direction D2 on the substrate 300, and a plurality of bit line structures 595 may be spaced apart from each other in the first direction D1.

The fourth and fifth insulation patterns 610 and 620 may be disposed on the fourth opening 440, and may contact a lower sidewall of the bit line structure 595. The fourth insulation pattern 610 may include an oxide, e.g., silicon oxide, and the fifth insulation pattern 620 may include an insulating nitride, e.g., silicon nitride.

The first insulation pattern structure 435 may be disposed under the bit line structure 595 on the active pattern 305 and the isolation pattern 310, and may include first, second and third insulation patterns 405, 415 and 425 sequentially stacked in the vertical direction. The first and third insulation patterns 405 and 425 may include an oxide, e.g., silicon oxide, and the second insulation pattern 415 may include an insulating nitride, e.g., silicon nitride.

The contact plug structure may include a lower contact plug 675, a metal silicide pattern 700 and an upper contact plug 755 sequentially stacked on the active pattern 305 and the isolation pattern 310 in the vertical direction.

The lower contact plug 675 may contact the upper surface of each of opposite end portions in the third direction D3 of the active pattern 305. In example implementations, a plurality of lower contact plugs 675 may be spaced apart from each other in the second direction D2 between neighboring ones of the bit line structures 595 in the first direction D1, and the second capping pattern 685 may be disposed between neighboring ones of the lower contact plugs 675 in the second direction D2. The second capping pattern 685 may include an insulating nitride, e.g., silicon nitride.

The lower contact plug 675 may include, e.g., doped polysilicon, and the metal silicide pattern 700 may include, e.g., titanium silicide, cobalt silicide, nickel silicide, etc.

The upper contact plug 755 may include a second metal pattern 745 and a second barrier pattern 735 covering a lower surface of the second metal pattern 745. The second metal pattern 745 may include a metal, e.g., tungsten, and the second barrier pattern 735 may include a metal nitride, e.g., titanium nitride.

In some implementations, a plurality of upper contact plugs 755 may be spaced apart from each other in each of the first and second directions D1 and D2, and may be arranged in a honeycomb pattern or a lattice pattern in a plan view. Each of the upper contact plugs 755 may have a shape of, e.g., a circle, an ellipse or a polygon in a plan view.

The spacer structure 665 may include a first spacer 600 covering a sidewall of the bit line structure 595 and a sidewall of the third insulation pattern 425, an air spacer 635 on a lower outer sidewall of the first spacer 600, and a third spacer 650 covering an outer sidewall of the air spacer 635, a sidewall of the first insulation pattern structure 435 and upper surfaces of the fourth and fifth insulation patterns 610 and 620.

Each of the first and third spacers 600 and 650 may include an insulating nitride, e.g., silicon nitride, and the air spacer 895 may include air.

The fourth spacer 690 may be disposed on an outer sidewall of a portion of the first spacer 600 on an upper sidewall of the bit line structure 595, and may cover a top of the air spacer 635 and an upper surface of the third spacer 650. The fourth spacer 690 may include an insulating nitride, e.g., silicon nitride.

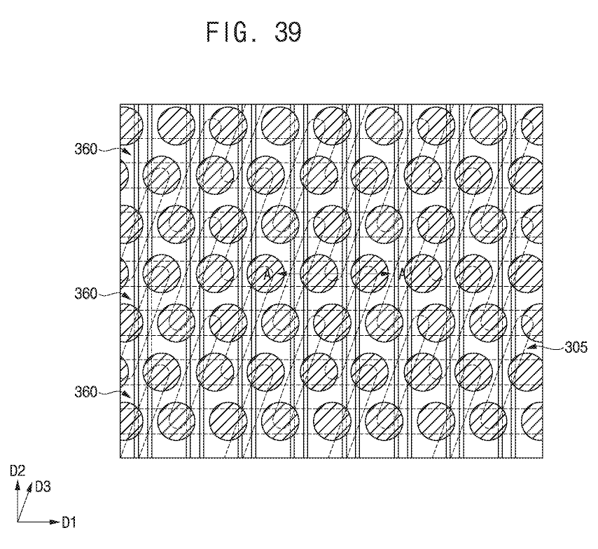

Referring to FIGS. 12 and 13 together with FIGS. 39 to 41, the second insulation pattern structure 790 may include a sixth insulation pattern 770 and a seventh insulation pattern 780. The sixth insulation pattern 770 may be disposed on an inner wall of a ninth opening 760 extending through the upper contact plug 755, a portion of the insulation structure included in the bit line structure 595, and portions of the first, third and fourth spacers 600, 650 and 690 to surround the upper contact plug 755 in a plan view. The seventh insulation pattern 780 may be disposed on the sixth insulation pattern 770, and may fill a remaining portion of the ninth opening 760. The top of the air spacer 635 may be closed by the sixth insulation pattern 770.

The sixth and seventh insulation patterns 770 and 780 may include an insulating nitride, e.g., silicon nitride.

The first etch stop layer 30 may be disposed on the sixth and seventh insulation patterns 770 and 780, the upper contact plug 755 and the second capping pattern 685.

The capacitor 110 may contact an upper surface of the upper contact plug 775.

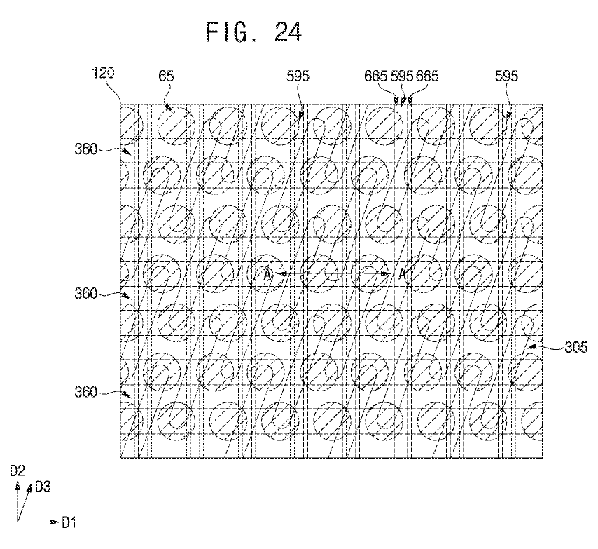

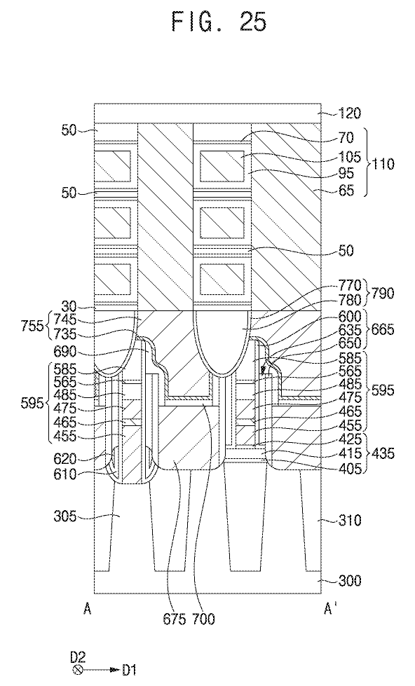

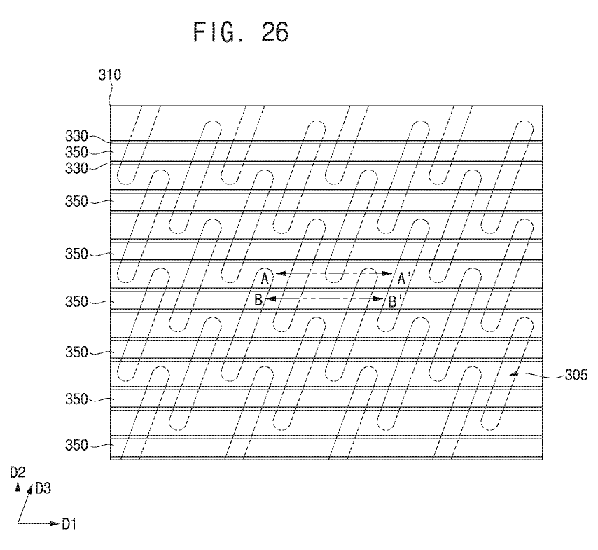

FIGS. 26, 27, 28, 29, 30, 31, 32, 33, 34, 35, 36, 37, 38, 39, 40, and 41, are plan views and cross-sectional views illustrating an example of a method of manufacturing a semiconductor device. Particularly, FIGS. 26, 28, 31, 35 and 39 are the plan views, FIG. 27 includes cross-sectional views taken along lines A-A’ and B-B’, respectively, of FIG. 26, and FIGS. 29-30, 32-34, 36-38 and 40-41 are cross-sectional views taken along lines A-A’ of corresponding plan views, respectively.

This method may be an application of the forming method illustrated with reference to FIGS. 4 to 12 and FIGS. 1 to 3 to a method of manufacturing a DRAM device, and repeated explanations of the method of forming the capacitor structure are omitted herein.

Referring to FIGS. 26 and 27, an upper portion of a substrate 300 may be removed to form a first recess, and an isolation pattern 310 may be formed in the first recess.

As the first recess is formed on the substrate 300, an active pattern 305 may be defined on the substrate 300, and a sidewall of the active pattern 305 may be covered by the isolation pattern 310.

The active pattern 305 and the isolation pattern 310 on the substrate 300 may be partially etched to form a second recess extending in the first direction D1, and a gate structure 360 may be formed in the second recess. In some implementations, the gate structure 360 may extend in the first direction D1, and a plurality of gate structures 360 may be spaced apart from each other in the second direction D2.

Referring to FIGS. 28 and 29, an insulation layer structure 430 may be formed on the active pattern 305, the isolation pattern 310 and the gate structure 360. The insulation layer structure 430 may include first, second and third insulation layers 400, 410 and 420 sequentially stacked in the vertical direction.

The insulation layer structure 430 may be patterned, and the active pattern 305, the isolation pattern 310 and the gate mask 350 of the gate structure 360 may be partially etched by an etching process using the patterned insulation layer structure 430 as an etching mask to form a fourth opening 440. In some implementations, the insulation layer structure 430 remaining after the etching process may have a shape of, e.g., a circle or an ellipse in a plan view, and a plurality of insulation layer structures 430 may be spaced apart from each other in the first and second directions D1 and D2. Each of the insulation layer structures 430 may overlap edge portions in the third direction D3 of neighboring active patterns 305, respectively.

Referring to FIG. 30, a first conductive layer 450, a first barrier layer 460, a second conductive layer 470 and a first mask layer 480 may be sequentially stacked on the insulation layer structure 430, and the active pattern 305, the isolation pattern 310 and the gate structure 360 exposed by the fourth opening 440, which may collectively form a conductive layer structure. The first conductive layer 450 may fill the fourth opening 440.

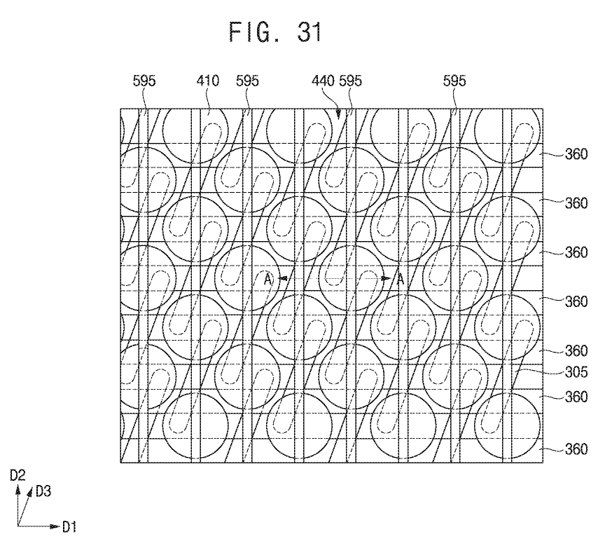

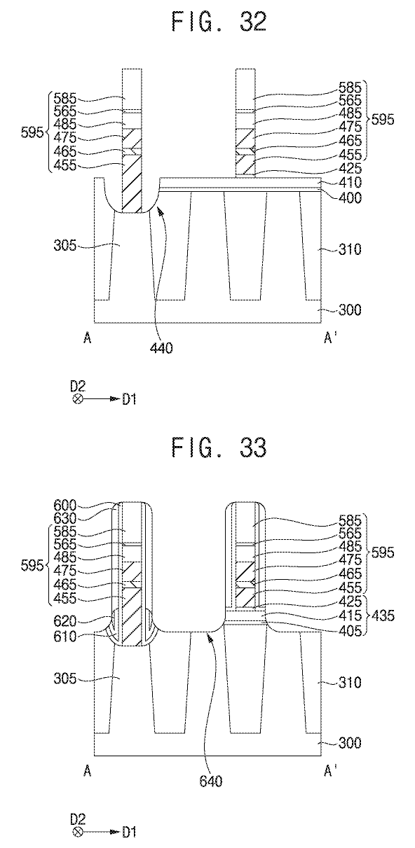

Referring to FIGS. 31 and 32, a second etch stop layer and a first capping layer may be sequentially stacked on the conductive layer structure, and the first capping layer may be etched to form a first capping pattern 585. The second etch stop layer, the first mask layer 480, the second conductive layer 470, the first barrier layer 460 and the first conductive layer 450 may be sequentially etched by an etching process using the first capping pattern 585 as an etching mask.

In some implementations, the first capping pattern 585 may extend in the second direction D2, and a plurality of first capping patterns 585 may be spaced apart from each other in the first direction D1.

By the etching process, a first conductive pattern 455, a first barrier pattern 465, a second conductive pattern 475, a first mask 485, a second etch stop pattern 565 and the first capping pattern 585 may be sequentially stacked on the fourth opening 440, and a third insulation pattern 425, the first conductive pattern 455, the first barrier pattern 465, the second conductive pattern 475, the first mask 485, the second etch stop pattern 565 and the first capping pattern 585 may be sequentially stacked on the second insulation layer 410 of the insulation layer structure 430 at an outside of the fourth opening 440.

Hereinafter, the first conductive pattern 455, the first barrier pattern 465, the second conductive pattern 475, the first mask 485, the second etch stop pattern 565 and the first capping pattern 585 sequentially stacked may be referred to as a bit line structure 595. The first conductive pattern 455, the first barrier pattern 465 and the second conductive pattern 475 may collectively form a conductive structure, and the first mask 485, the second etch stop pattern 565 and the first capping pattern 585 may collectively form an insulation structure. In some implementations, the bit line structure 595 may extend in the second direction D2 on the substrate 300, and a plurality of bit line structures 595 may be spaced apart from each other in the first direction D1.

Referring to FIG. 33, a first spacer layer may be formed on the substrate 300 having the bit line structure 595 thereon, and fourth and fifth insulation layers may be sequentially formed on the first spacer layer.

The first spacer layer may also cover a sidewall of the third insulation pattern 425 under a portion of the bit line structure 595 on the second insulation layer 410, and the fifth insulation layer may fill a remaining portion of the fourth opening 440.

The fourth and fifth insulation layers may be etched by an etching process. In some implementations, the etching process may be performed by a wet etching process using an etching solution, e.g., H₂PO₃, SC1, HF, etc., and portions of the fourth and fifth insulation layers at the outside of the fourth opening 440 may be removed. Thus, a portion of the first spacer layer at the outside of the fourth opening 440 may be exposed, and portions of the fourth and fifth insulation layers in the fourth opening 440 may form fourth and fifth insulation patterns 610 and 620, respectively.

A second spacer layer may be formed on the exposed portion of the first spacer layer and the fourth and fifth insulation patterns 610 and 620 in the fourth opening 440, and may be anisotropically etched to form a second spacer 630 on the exposed portion of the first spacer and the fourth and fifth insulation patterns 610 and 620 to cover a sidewall of the bit line structure 595.

A dry etching process may be performed using the first capping pattern 585 and the second spacer 630 as an etching mask to form a fifth opening 640 exposing an upper surface of the active pattern 305, and upper surfaces of the isolation pattern 310 and the gate mask 350 may also be exposed by the fifth opening 640.

By the dry etching process, a portion of the first spacer layer on the first capping pattern 585 and the second insulation layer 410 may be removed, and thus a first spacer 600 covering a sidewall of the bit line structure 595 may be formed. Additionally, by the dry etching process, the first and second insulation layers 400 and 410 may also be partially etched so that first and second insulation patterns 405 and 415 may remain under the bit line structure 595. The first to third insulation patterns 405, 415 and 425 sequentially stacked under the bit line structure 595 may collectively form a first insulation pattern structure 435.

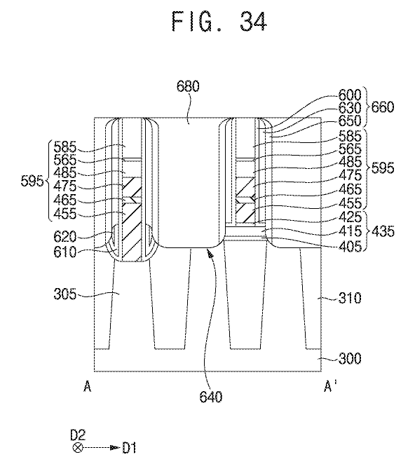

Referring to FIG. 34, a third spacer layer may be formed on an upper surface of the first capping pattern 585, an outer sidewall of the second spacer 630, upper surfaces of the fourth and fifth insulation patterns 610 and 620, and the upper surfaces of the active pattern 305, the isolation pattern 310 and the gate mask 350 exposed by the fifth opening 640, and may be anisotropically etched to form a third spacer 650 on the sidewall of the bit line structure 595.

The first, second and third spacers 600, 630 and 650 sequentially stacked on the sidewall of the bit line structure 595 may collectively form a preliminary spacer structure 660.

A sacrificial layer may be formed on the substrate 300 to fill the fifth opening 640, and may be planarized until the upper surface of the first capping pattern 585 is exposed to form a sacrificial pattern 680 in the fifth opening 640.

In some implementations, the sacrificial pattern 680 may extend in the second direction D2, and a plurality of sacrificial patterns 680 may be spaced apart from each other in the first direction D1 by the bit line structures 595. The sacrificial pattern 680 may include an oxide, e.g., silicon oxide.

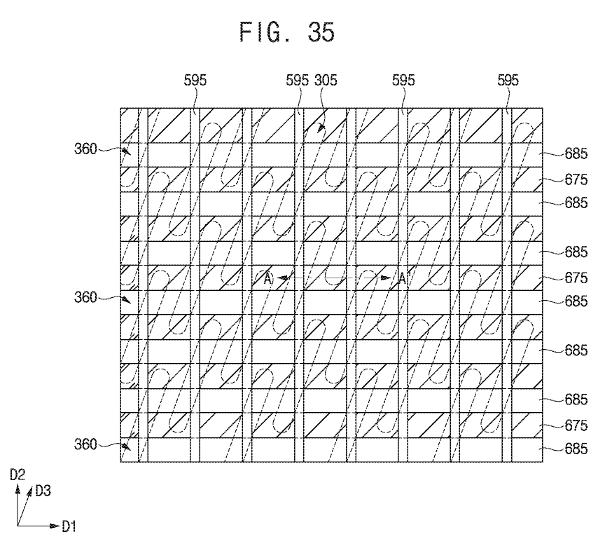

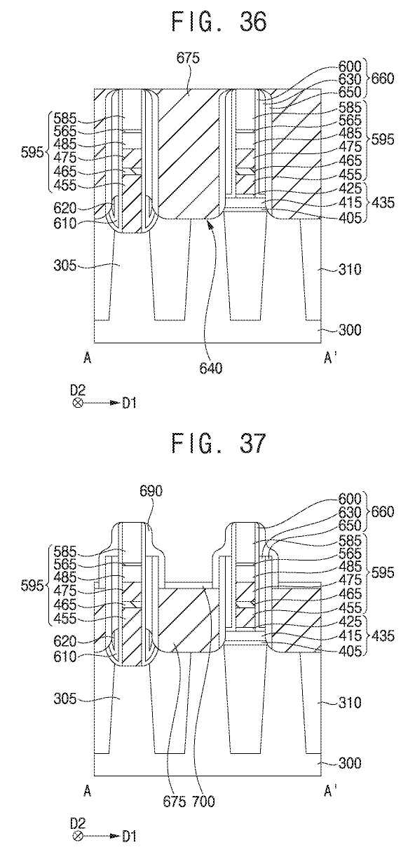

Referring to FIGS. 35 and 36, a second mask including a plurality of sixth openings, each of which may extend in the first direction D1, spaced apart from each other in the second direction D2 may be formed on the first capping pattern 585, the sacrificial pattern 680 and the preliminary spacer structure 660, and the sacrificial pattern 680 may be etched by an etching process using the second mask as an etching mask.

In some implementations, each of the sixth openings may overlap in the vertical direction an area between the gate structures 360. By the etching process, a seventh opening exposing the upper surfaces of the active pattern 305 and the isolation pattern 310 may be formed between the bit line structures 595.

After removing the second mask, a lower contact plug layer may be formed to fill the seventh opening, and may be planarized until upper surfaces of the first capping pattern 585, the sacrificial pattern 680 and the preliminary spacer structure 660 are exposed. Thus, the lower contact plug layer may be divided into a plurality of lower contact plugs 675 spaced apart from each other in the second direction D2 between the bit line structures 595. Additionally, the sacrificial pattern 680 extending in the second direction D2 between the bit line structures 595 may be divided into a plurality of parts spaced apart from each other in the second direction D2 by the lower contact plugs 675.

The sacrificial pattern 680 may be removed to form an eighth opening, and a second capping pattern 685 may be formed in the eighth opening. In some implementations, the second capping pattern 685 may overlap the gate structure 360 in the vertical direction.

Referring to FIG. 37, an upper portion of the lower contact plug 675 may be removed to expose an upper portion of the preliminary spacer structure 660 on the sidewall of the bit line structure 595, and upper portions of the second and third spacers 630 and 650 of the preliminary spacer structure 660 may be removed.

An upper portion of the lower contact plug 675 may be further removed. Thus, an upper surface of the lower contact plug 675 may be lower than upper surfaces of the second and third spacers 630 and 650.

A fourth spacer layer may be formed on the bit line structure 595, the preliminary spacer structure 660, the second capping pattern 685 and the lower contact plug 675, and may be anisotropically etched to form a fourth spacer 690 covering an upper portion of the preliminary spacer structure 660 on each of opposite sidewalls in the first direction D1 of the bit line structure 595, and thus an upper surface of the lower contact plug 675 may be exposed.

A metal silicide pattern 700 may be formed on the upper surface of the lower contact plug 675. In some implementations, the metal silicide pattern 700 may be formed by forming a first metal layer on the first and second capping patterns 585 and 685, the fourth spacer 690 and the lower contact plug 675, performing a heat treatment process, and removing an unreacted portion of the first metal layer.

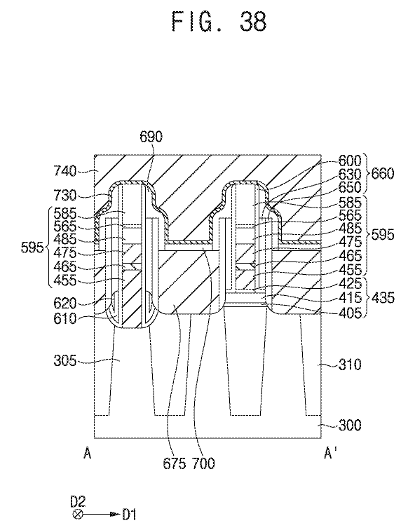

Referring to FIG. 38, a second barrier layer 730 may be formed on the first and second capping patterns 585 and 685, the fourth spacer 690, the metal silicide pattern 700 and the lower contact plug 675, and a second metal layer 740 may be formed on the second barrier layer 730 to fill a space between the bit line structures 595.

A planarization process may be further performed on an upper portion of the second metal layer 740. The planarization process may include a CMP process and/or an etch back process.

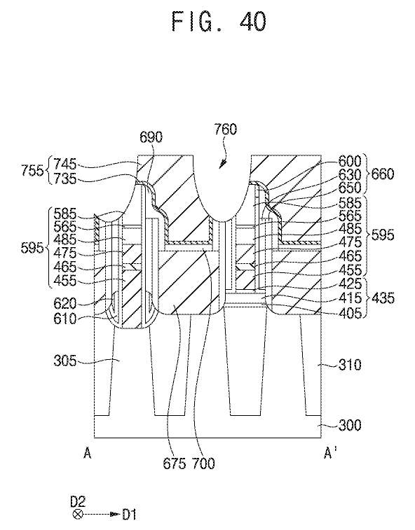

Referring to FIGS. 39 and 40, the second metal layer 740 and the second barrier layer 730 may be patterned to form an upper contact plug 755, and a ninth opening 760 may be formed between the upper contact plugs 755.

The ninth opening 760 may be formed by partially removing the first and second capping patterns 585 and 685, the preliminary spacer structure 660 and the fourth spacer 690 as well as the second metal layer 740 and the second barrier layer 730.

The upper contact plug 755 may include a second metal pattern 745 and a second barrier pattern 735 covering a lower surface of the second metal pattern 745. In some implementations, the upper contact plug 755 may have a shape of, e.g., a circle, an ellipse, a polygon, a polygon with rounded corners, etc., and may be arranged in a honeycomb pattern in the first and second directions D1 and D2.

The lower contact plug 675, the metal silicide pattern 700 and the upper contact plug 755 sequentially stacked may collectively form a contact plug structure.

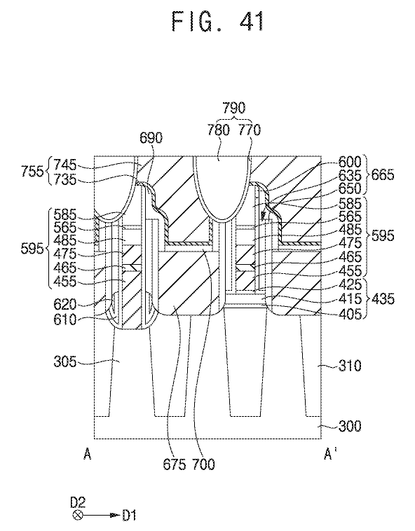

Referring to FIG. 41, the second spacer 630 included in the preliminary spacer structure 660 exposed by the ninth opening 760 may be removed to form an air gap, a sixth insulation pattern 770 may be formed on a bottom and a sidewall of the ninth opening 760, and a seventh insulation pattern 780 may be formed to fill a remaining portion of the ninth opening 760.

The sixth and seventh insulation patterns 770 and 780 may form a second insulation pattern structure 790.

A top of the air gap may be covered by the sixth insulation pattern 770, and thus an air spacer 635 may be formed. The first spacer 600, the air spacer 635 and the third spacer 650 may collectively form a spacer structure 665.

Referring to FIGS. 24 and 25 again, processes substantially the same as or similar to those illustrated with respect to FIGS. 4 to 12 and FIGS. 1 to 3 may be performed to form the capacitor 110, the first etch stop layer 30, the support layer 50 and the upper plate electrode 120.

The lower electrode 65 of the capacitor 110 may contact an upper surface of the upper contact plug 775.

According to a method of forming a capacitor structure, mold layers and support layers may be alternately and repeatedly stacked on a substrate in a vertical direction perpendicular to an upper surface of the substrate. A lower electrode extending through the mold layers and the support layers may be formed. The mold layers may be removed by an etching process to form a first opening exposing a portion of the support layers and a portion of the lower electrode. A first deposition process may be performed to form a first interface pattern on a surface of the portion of the support layers exposed by the first opening. The first interface pattern may include a plurality of first patterns spaced apart from each other in a horizontal direction parallel to the upper surface of the substrate.

In example embodiments, the first deposition process may include providing a precursor onto the substrate, providing a reactant onto the substrate so as to be reacted with the precursor, and performing a purge process onto the substrate.

In example embodiments, the first deposition process may be a selective deposition process, and the first interface pattern may be formed outside a sidewall of the lower electrode.

In example embodiments, during the first deposition process, a second interface pattern may be formed on a sidewall of the portion of the lower electrode exposed by the first opening. The second interface pattern may include a plurality of second patterns spaced apart from each other in the vertical direction.

In example embodiments, a number of the plurality of first patterns of the first interface pattern per unit area may be greater than a number of the plurality of second patterns of the second interface pattern per unit area.

In example embodiments, prior to performing the first deposition process, a second deposition process may be performed to form a second interface pattern on a surface of the portion of the support layers exposed by the first opening. The first deposition process may include forming the first interface pattern on a surface of the second interface pattern exposed by the first opening.

In example embodiments, after forming the first interface pattern, a dielectric pattern and an upper electrode may be sequentially formed in the first opening. The dielectric pattern may contact the first interface pattern and the support layers.

In example embodiments, the first interface pattern may include at least one of niobium, tantalum, vanadium, molybdenum, tungsten, ruthenium, titanium, zirconium, or hafnium.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example implementations and is not to be construed as limiting thereof. Although a few example implementations have been described, those skilled in the art will readily appreciate that many modifications are possible in the example implementations without materially departing from the novel teachings and advantages of the present disclosure.

What is claimed is:

1. A capacitor structure comprising:
a lower electrode on a substrate;
a support layer on a sidewall of a first portion of the lower electrode;
a first interface pattern on a surface of the support layer, the first interface pattern including a plurality of first patterns spaced apart from each other in a horizontal direction, the horizontal direction being parallel to an upper surface of the substrate;
a dielectric pattern on a sidewall of a second portion of the lower electrode; and
an upper electrode on a sidewall of the dielectric pattern.

2. The capacitor structure according to claim 1, wherein the first interface pattern includes at least one of niobium, tantalum, vanadium, molybdenum, tungsten, ruthenium, titanium, zirconium, or hafnium.

3. The capacitor structure according to claim 1, wherein the surface of the support layer is a lower surface or an upper surface of the support layer, the first interface pattern is disposed on the lower surface and the upper surface of the support layer, and the first interface pattern contacts the dielectric pattern.

4. The capacitor structure according to claim 1, further comprising a second interface pattern between the sidewall of the second portion of the lower electrode and the dielectric pattern,
wherein the second interface pattern includes a plurality of second patterns spaced apart from each other in a vertical direction, the vertical direction being perpendicular to the upper surface of the substrate.

5. The capacitor structure according to claim 4, wherein a number of the plurality of first patterns of the first interface pattern per unit area is greater than a number of the plurality of second patterns of the second interface pattern per unit area.

6. The capacitor structure according to claim 1, further comprising a second interface pattern between the surface of the support layer and the first interface pattern, the second interface pattern including an oxide,
wherein the first interface pattern is disposed on a surface of the second interface pattern.

7. The capacitor structure according to claim 6, further comprising a third interface pattern between the sidewall of the second portion of the lower electrode and the dielectric pattern,
wherein the third interface pattern includes a plurality of second patterns spaced apart from each other in a vertical direction, the vertical direction being perpendicular to the upper surface of the substrate.

8. The capacitor structure according to claim 7, wherein a number of the plurality of first patterns of the first interface pattern per unit area is greater than a number of the plurality of second patterns of the third interface pattern per unit area.

9. The capacitor structure according to claim 1, further comprising an upper plate electrode on an upper surface of the lower electrode and an upper surface of the support layer, the upper plate electrode including doped silicon-germanium.

10. The capacitor structure according to claim 1, wherein the lower electrode has a shape of a pillar or a cup.

11. A capacitor structure comprising:
a lower electrode on a substrate, the lower electrode including a first metal;
a support layer on a sidewall of a first portion of the lower electrode;
a first interface pattern disposed on a surface of the support layer and protruding from the surface of the support layer in a vertical direction, the vertical direction being perpendicular to an upper surface of the substrate, the first interface pattern including a second metal different from the first metal;
a dielectric pattern on a sidewall of a second portion of the lower electrode; and
an upper electrode on a sidewall of the dielectric pattern.

12. The capacitor structure according to claim 11, wherein the surface of the support layer is a lower surface or an upper surface of the support layer, the first interface pattern is disposed on the lower surface and the upper surface of the support layer, and the first interface pattern protrudes from the lower surface downwardly and protrudes from the upper surface upwardly.

13. The capacitor structure according to claim 11, further comprising a second interface pattern between the sidewall of the second portion of the lower electrode and the dielectric pattern, the second interface pattern including the second metal,
wherein the dielectric pattern contacts the second interface pattern.

14. The capacitor structure according to claim 11, further comprising a second interface pattern on the surface of the support layer, the second interface pattern including an oxide,
wherein the first interface pattern protrudes from a surface of the second interface pattern in the vertical direction.

15. The capacitor structure according to claim 11, further comprising an etch stop layer on a sidewall of a third portion of the lower electrode,
wherein the first interface pattern is disposed on an upper surface of the etch stop layer.

16. A semiconductor device comprising:
an active pattern on a substrate;
a gate structure in an upper portion of the active pattern, the gate structure extending in a first direction parallel to an upper surface of the substrate;
a bit line structure extending in a second direction, the second direction being parallel to the upper surface of the substrate and crossing the first direction, the bit line structure being on a central portion of the active pattern;
a contact plug structure on a first end portion and a second end portion of the active pattern, the first end portion being opposite to the second end portion; and
a capacitor structure on the contact plug structure,
wherein the capacitor structure includes
a lower electrode on the contact plug structure,
a support layer on a sidewall of a first portion of the lower electrode,
a first interface pattern on a surface of the support layer, the first interface pattern including a plurality of first patterns spaced apart from each other in a horizontal direction, the horizontal direction being parallel to an upper surface of the substrate,
a dielectric pattern on a sidewall of a second portion of the lower electrode, and
an upper electrode on a sidewall of the dielectric pattern.

17. The capacitor structure according to claim 16, wherein each first pattern of the plurality of first patterns of the first interface pattern protrudes from the surface of the support layer.

18. The capacitor structure according to claim 16, further comprising a second interface pattern between the sidewall of the second portion of the lower electrode and the dielectric pattern,
wherein the second interface pattern includes a plurality of second patterns spaced apart from each other in a vertical direction, the vertical direction being perpendicular to the upper surface of the substrate.

19. The capacitor structure according to claim 18, wherein a number of the plurality of first patterns of the first interface pattern per unit area is greater than a number of the plurality of second patterns of the second interface pattern per unit area.

20. The capacitor structure according to claim 16, further comprising a second interface pattern between the surface of the support layer and the first interface pattern, the second interface pattern including an oxide,
wherein each first pattern of the plurality of first patterns of the first interface pattern protrudes from a surface of the second interface pattern.
